(19) United States
(12) Patent Application Publication
(10) Pub. No.: US 2026/0157088 A1
(43) Pub. Date: Jun. 4, 2026

(54) ORGANIC ELECTROLUMINESCENT DEVICES

(71) Applicant: Universal Display Corporation, Ewing, NJ (US)

(72) Inventors: Michael Hack, Carmel, CA (US); Michael Stuart Weaver, Princeton, NJ (US); Nicholas J. Thompson, New Hope, PA (US); Michael Fusella, Lawrenceville, NJ (US)

(21) Appl. No.: 19/330,906

(22) Filed: Sep. 17, 2025

Related U.S. Application Data
(60) Provisional application No. 63/699,436, filed on Sep. 26, 2024.
(60) Provisional application No. 63/703,591, filed on Oct. 4, 2024.

(51) Int. Cl. H10K 59/80; H10K 59/35

(52) U.S. Cl. CPC H10K 59/876; H10K 59/35

(57) ABSTRACT

A device is provided that includes a full color organic light emitting diode (OLED) having a plurality of pixels, where each pixel has a plurality of sub-pixels. A first pixel of the plurality of pixels may include a first sub-pixel having a top emission device or a bottom emission device, and a second sub-pixel comprises a first plasmonic stack. In some embodiments, a full color organic light emitting diode (OLED) may be provided having a plurality of pixels, where each pixel comprises a plurality of sub-pixels. At least one sub-pixel of the plurality of sub-pixels may be configured differently from the other sub-pixels by a different angular emission profile and/or a different cathode material or organic stack design.

### CROSS-REFERENCE TO RELATED APPLICATIONS

This application claims priority to U.S. Patent Application Ser. No. 63/703,591, filed Oct. 4, 2024, and to U.S. Patent Application Ser. No. 63/699,436, filed Sep. 24, 2024, the entire contents of each are incorporated herein by reference.

### FIELD

The present invention relates to devices and techniques for fabricating organic emissive devices, such as organic light emitting diodes, that combine plasmonic and cavity sub-pixels to increase efficiency, lifetime, and display viewing angle, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. As used herein, a near infrared “NIR” layer, material, region, or device refers to one that emits light in the range of about 700-1400 nm or having a highest peak in its emission spectrum in that region. As used herein, a short wavelength infrared “SWIR” layer, material, region, or device refers to one that emits light in the range of about 1400-3000 nm or having a highest peak in its emission spectrum in that region. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more devices selected from a consumer product, an electronic component module, and/or a lighting panel.

According to an embodiment, a device may include a full color organic light emitting diode (OLED) having a plurality of pixels, where each pixel has a plurality of sub-pixels. A first pixel of the plurality of pixels may include a first sub-pixel having a top emission device or a bottom emission device, and a second sub-pixel having a first plasmonic stack. The top emission device may be a cavity structure.

For the first pixel, a third sub-pixel may include a structure of a cavity, a plasmonic stack, and/or a bottom-emission device.

The first plasmonic stack may include an organic emissive layer having an organic emissive material disposed over the electrode, where the organic emissive material may have a total non-radiative decay rate constant

$${k}_{n o n - r ad}^{0} ,$$

a total radiative decay rate constant

$${k}_{ra d}^{0} ,$$

a total non-radiative decay rate constant due to the enhancement layer

$${k}_{non - r ad}^{plasmon} ,$$

and may have a total radiative decay rate constant due to the enhancement layer

$${k}_{r ad}^{plasmon} .$$

The first plasmonic stack may include an enhancement layer having a plasmonic material exhibiting surface plasmon resonance that non-radiatively couples to the organic emissive material and transfer excited state energy from the emissive material to non-radiative mode of surface plasmon polaritons, disposed over the organic emissive layer opposite from the first electrode. The enhancement layer may be provided no more than a threshold distance away from the organic emissive layer, where the threshold distance may be a distance at which

$$\frac{{k}_{r ad}^{plasmon}}{{k}_{non - r ad}^{plasmon}} = \frac{{k}_{ra d}^{0}}{{k}_{non - ra d}^{0}} .$$

The first plasmonic stack may include an outcoupling layer disposed over the enhancement layer, where the outcoupling layer scatters or extracts the energy from the surface plasmon polaritons as photons to free space. The outcoupling layer may be disposed over all sub-pixels of the first pixel, or the outcoupling layer may be disposed over only one or more sub-pixels in the first pixel.

When the first pixel is capable of emitting white light at a DCIP3 white point, greater than 1%, greater than 3%, greater than 5%, greater than 10%, greater than 25%, or greater than 50% of photons of light emitted by the first pixel may be emitted from a plasmon mode of the first sub-pixel.

Greater than 1%, greater than 5%, greater than 10%, greater than 15%, greater than 20%, or greater than 25% of an absolute EQE of the first pixel may be attributable to emission from a plasmon mode of the first sub-pixel.

Greater than 1%, greater than 5%, greater than 10%, greater than 15%, greater than 20%, or greater than 25% of the EQE of the OLED when rendering a uniform D65 white point image may be attributable to emission from a plasmon mode.

The first plasmonic stack may include a color altering layer disposed over the outcoupling layer, where there is an overlap between a transmission spectrum of the color altering layer and an emission spectrum of light output from the outcoupling layer. The enhancement layer may be an electrode of the plasmonic stack. The enhancement layer may be an electrode for the other sub-pixels of the pixel. In other words, the enhancement layer for a first sub-pixel may be a layer in a second sub-pixel. Here, the enhancement layer may be an electrode (i.e., anode or cathode) in the second sub-pixel or another layer located within the second sub-pixel.

The first plasmonic stack may include an enhancement layer having a plasmonic material exhibiting surface plasmon resonance that non-radiatively couples to the organic emissive material and transfers excited state energy from the emissive material to non-radiative mode of surface plasmon polaritons, disposed over the organic emissive layer opposite from the first electrode, and an organic emissive layer having an organic emissive material disposed over the electrode, the organic emissive material having a total non-radiative decay rate constant and a total radiative decay rate constant due to the presence of the enhancement layer. The enhancement layer may be provided no more than a threshold distance away from the organic emissive layer, the threshold distance being a distance at which the total non-radiative decay rate constant is equal to the total radiative decay rate constant.

The first sub-pixel of the device may include an emissive material configured to emit blue light. The emissive material may be configured to emit deep blue light. The second sub-pixel may be configured to emit yellow light. At least one of the first and second sub-pixels may include a color altering layer. The first pixel may include at least three sub-pixels, and where each of the at least three sub-pixels, other than the sub-pixel having the material configured to emit deep blue light, may be configured to emit green light or red light. At least one of the at least three sub-pixels may be configured to emit green light. At least one of the at least three sub-pixels may be configured to emit red light. The first pixel may include at least four sub-pixels. At least one of the at least four sub-pixels, other than the sub-pixel having the material configured to emit deep blue light or light blue light, may include a color altering layer configured to emit yellow light, green light or red light. At least one of the at least four sub-pixels may be configured to emit green light. At least one of the at least four sub-pixels is configured to emit red light. Two sub-pixels of the at least four sub-pixels may have the same emissive layer. The first sub-pixel may be configured to emit deep blue light or light blue light, and the at least one other sub-pixel of the at least four sub-pixels is configured to emit deep blue light or light blue light.

The first pixel of the device may include at least three sub-pixels, and the first pixel may include an outcoupling layer that outcouples light from at least one sub-pixel of the three sub-pixels. The outcoupling layer may emit yellow light, and each of the three or more sub-pixels may have a color altering layer configured to emit yellow, green, or red light. The outcoupling layer may be patterned over each of the plurality of sub-pixels that are plasmonic, and not patterned over each of the plurality of sub-pixels that are not plasmonic. Alternatively, the outcoupling layer may be patterned over each of the plurality of sub-pixels, regardless of plasmonic or not plasmonic. One of the at least three sub-pixels of the device may be configured to emit green light, and one of the at least three sub-pixels may be configured to emit red light. The device may include not more than two emissive layer depositions. The two emissive depositions may include yellow and blue emissive materials. The device may include not more than three emissive layer depositions.

The two sub-pixels of the first pixel of the device may be configured to emit light having a same first color. The two sub-pixels may be the first sub-pixel and the second sub-pixel.

The first plasmonic stack of the device may include a plurality of nanoparticles and the nanoparticles have an average nanoparticle size. In other words, the sizing, on average, of all of the nanoparticles is an average nanoparticle size. In an embodiment, each plasmonic sub-pixel in the first pixel may include nanoparticles having a size coefficient variation of not more than 15%. Each plasmonic sub-pixel in the device may include nanoparticles having a size coefficient variation of not more than 15%. A size coefficient variation is the coefficient of variation, a statistical measure of relative variability that expresses the standard deviation as a percentage of the mean. The size coefficient variation is calculated as (Standard Deviation/Mean)×100%. The plurality of nanoparticles may have maximum diameters that vary by not more than 70 nm from each other. All nanoparticles disposed over plasmonic sub-pixels in the device may have maximum diameters that vary by not more than 70 nm from each other. The nanoparticle size may be selected to out-couple plasmon energy from the first plasmonic stack, where the plasmonic stack may be configured to emit red light and/or green light. The plasmonic stack may include a dielectric spacer material having a refractive index selected based on a color of light emitted by the organic emissive material. In an embodiment, the dielectric spacer material (i.e., dielectric spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of either electrode, outside of the plasmonic stack. In yet another embodiment, the dielectric spacer material may be located between the enhancement layer and the outcoupling layer or may be integrated within the outcoupling layer. The second sub-pixel of the device may be configured to emit red light or green light. The nanoparticles may be coated with a dielectric material. The plasmonic stack may include a dielectric spacer material, where the dielectric material may have a refractive index selected based on a color of light emitted by the organic emissive material. The dielectric spacer material in each plasmonic sub-pixel may have a spacer size that varies by not more than 10%. Each plasmonic sub-pixel in the device may include a dielectric spacer material having a spacer size that varies by not more than 50%.

The device may include a capping layer disposed over the plasmonic stack. In some embodiments, a capping layer may be disposed over the non-plasmonic sub-pixels (e.g., the cavity sub-pixels). The capping layer may be the same material to cover the plasmonic stack (i.e., the plasmonic sub-pixels) and non-plasmonic subpixels. In some embodiments, a first material may be used for a capping layer disposed over the plasmonic stack and/or plasmonic sub-pixels, and a second material may be used for a capping layer disposed over the non-plasmonic subpixels (e.g., the cavity sub-pixels).

The first pixel of the device may include a third sub-pixel. In this arrangement, the first sub-pixel may be configured to emit blue light, the second sub-pixel is configured to emit red light, and the third sub-pixel may include a second plasmonic stack and is configured to emit green light. An aperture ratio of the first sub-pixel may be larger than the aperture ratios for the second sub-pixel and the third sub-pixel. The aperture ratio for the first sub-pixel of the device may be greater than 40%, greater than 50%, or greater than 60%, and the aperture ratio for the second sub-pixel, the third sub-pixel, or both is less than 20%, less than 15%, or less than 10%. The cavity structure of the first sub-pixel may be a polariton enhanced Purcell effect device.

The second sub-pixel of the device may include a nanoparticle-based outcoupling scheme. The nanoparticle-based outcoupling scheme may include a first nanopatch antenna (NPA) array. The first NPA array may be disposed over a first dielectric material. In an embodiment, this nanoparticle-based outcoupling scheme may also be called an outcoupling layer.

The first pixel may include a fourth sub-pixel having at least one structure that may be a second cavity structure or bottom emission structure configured to emit yellow light and/or a second plasmonic stack configured to emit yellow light.

The first sub-pixel may be configured to emit blue light, the second sub-pixel is configured to emit red light, and the third sub-pixel may include at least one structure that is a third cavity structure or bottom emission structure configured to emit green light, and/or a third plasmonic stack configured to emit green light.

The first pixel may include a fourth sub-pixel having at least one structure that is a second cavity structure or bottom emission structure configured to emit blue light having a first peak wavelength, and/or a second plasmonic stack configured to emit blue light having the first peak wavelength. The first sub-pixel may be configured to emit blue light having a second peak wavelength different from the first peak wavelength, the second sub-pixel may include at least one structure that is a third cavity stack or bottom emission stack configured to emit red light, and/or a second plasmonic stack is configured to emit red light. The third sub-pixel may include at least one structure that is a fourth cavity stack or bottom emission stack configured to emit green light, and/or a third plasmonic stack configured to emit green light.

The first pixel may include a fourth sub-pixel configured to emit green light and may have a structure that is a cavity, a plasmonic device, and/or a bottom-emission device. The first sub-pixel may be configured to emit blue light having a first peak wavelength, the second sub-pixel may be configured to emit blue light having a second peak wavelength different from the first peak wavelength, and the third sub-pixel may be configured to emit red light from a structure that is a cavity structure, a plasmonic device, and/or a bottom-emission device.

The first pixel may include a fourth sub-pixel configured to emit green light from a second plasmonic stack, a fifth sub-pixel configured to emit blue light from a second cavity structure, and a sixth sub-pixel configured to emit blue light from a third plasmonic stack. The first sub-pixel may be configured to emit red light, the second sub-pixel may be configured to emit red light, and the third sub-pixel may be configured to emit green light from a third cavity structure.

The first sub-pixel of the device may have a different angular emission profile that the second sub-pixel.

An aperture ratio of the first sub-pixel of the device may be larger than the aperture ratio of the second sub-pixel. The aperture ratio for the first sub-pixel may be greater than 40%, greater than 50%, or greater than 60%, and the aperture ratio for the second sub-pixel may be less than 20%, less than 15%, or less than 10%.

The first pixel may include a sub-pixel having an emissive material of at least one of a fluorescent emissive material, a phosphorescent emissive material, a thermally activated delayed fluorescent (TADF) emissive material, phosphor sensitized fluorescent (PSF) emissive material, an inorganic emissive material and/or 2D dichalcogenide emissive material. At least one sub-pixel in the first pixel may include a tandem device. In an embodiment, the tandem device may include two or more plasmonic stacks, two or more non-plasmonic stacks, or two or more stacks where at least one is plasmonic and one is non-plasmonic. It should be noted, a non-plasmonic stack is a traditional OLED stack as described in connection with FIG. 1 and FIG. 2.

The first pixel may include two or more sub-pixels that have the same emissive material, where the two or more sub-pixels are configured to emit the same color light at different peak wavelengths from each other.

The second sub-pixel of the device may be configured to emit blue light, and the first sub-pixel of the device may be configured to emit red light, and/or green light.

The second sub-pixel of the device may be configured to emit blue light and/or green light, and the first sub-pixel of the device may be configured to emit red light.

The second sub-pixel of the device may be configured to emit blue light and/or red light, and the first sub-pixel of the device may be configured to emit green light.

The second sub-pixel of the device may be configured to emit green light, and the first sub-pixel of the device may be configured to emit red light and/or blue light.

The second sub-pixel of the device may be configured to emit green light and/or red light, and the first sub-pixel of the device may be configured to emit blue light.

The second sub-pixel of the device may be configured to emit red light, and the first sub-pixel of the device may be configured to emit green light and/or blue light.

The plasmonic stack of the second sub-pixel of the device may include an emitter having fluorescent material, which may be configured to emit blue light.

According to an embodiment, a device may include a full color organic light emitting diode (OLED) having a plurality of pixels, wherein each pixel has a plurality of sub-pixels, where, for a first pixel of the plurality of pixels a first sub-pixel comprises a top emission device or a bottom emission device or a plasmonic stack where an enhancement layer may be provided less than a threshold distance away from the organic emissive layer, and a second sub-pixel comprises a stack that has both cavity-like and plasmonic emission. The enhancement layer in this sub-pixel is provided more than a threshold distance away from the organic emissive layer, where the threshold distance is a distance at which

$$\frac{{k}_{r ad}^{plasmon}}{{k}_{non - r ad}^{plasmon}} = \frac{{k}_{ra d}^{0}}{{k}_{non - ra d}^{0}} .$$

The top emission device may be a cavity structure. The second sub-pixel includes may include an outcoupling layer, where the outcoupling layer scatters or extracts the energy from the surface plasmon polaritons as photons emitted from the device.

The device may be a consumer electronic device, where the device may be a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls having multiple displays tiled together, a theater or stadium screen, and/or a sign.

According to an embodiment, the device may include a full color organic light emitting diode (OLED) having a plurality of pixels, where each pixel includes a plurality of sub-pixels. At least one sub-pixel of the plurality of sub-pixels may be configured differently from the other sub-pixels by a different angular emission profile, and/or a different cathode material.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example RGB1B2 architecture according to an embodiment of the disclosed subject matter.

FIG. 4 shows an example YB plus CF architecture according to an embodiment of the disclosed subject matter.

FIG. 5 shows an example a plasmonic PHOLED (phosphorescent organic light-emitting diode) sub-pixel stack according to an embodiment of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

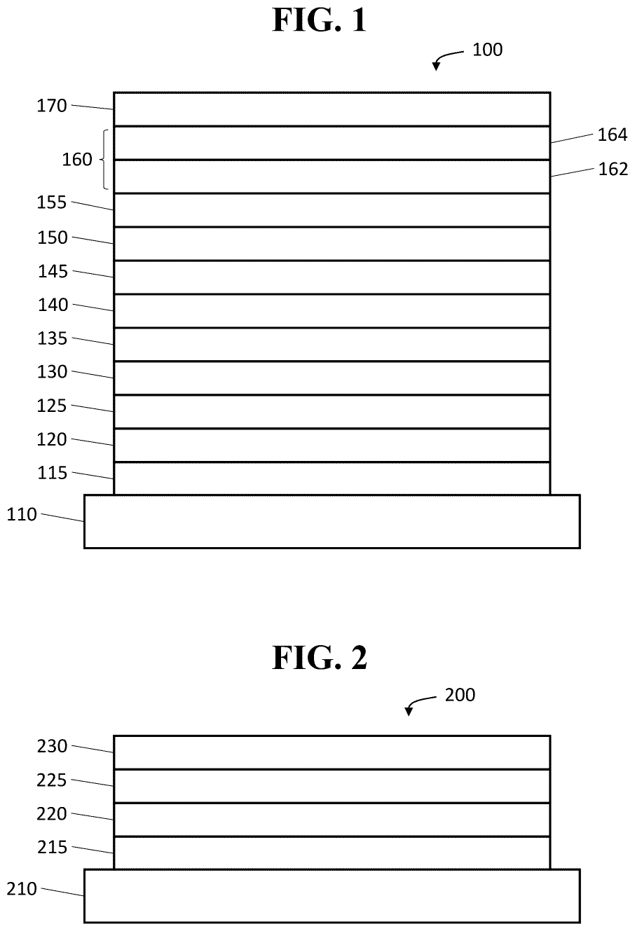

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety.

Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes.

Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant, as disclosed in U.S. Pat. No. 9,960,386 and incorporated by reference in its entirety. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric spacer layers can be disposed between the enhancement layer and the outcoupling layer. The plasmonic stack may include a dielectric spacer material (i.e., a dielectric spacer layer) having a refractive index selected based on a color of light emitted by the organic emissive material. In an embodiment, the dielectric spacer material (i.e., dielectric spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of either electrode, outside of the plasmonic stack. In yet another embodiment, the dielectric spacer material may be located between the enhancement layer and the outcoupling layer or may be integrated within the outcoupling layer. In some embodiments, the dielectric spacer layer may be found only in a plasmonic stack sub-pixel, only in a non-plasmonic stack sub-pixel or in both. Examples of material suitable for use in dielectric spacer layers include dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, and/or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In some embodiments, the outcoupling layer may have larger than wavelength-sized features that are arranged periodically, quasi-periodically, or randomly, or may have sub-wavelength-sized features that are arranged periodically, quasi-periodically, or randomly. In some embodiments, the outcoupling layer may have smaller than wavelength-sized features that are arranged periodically, quasi-periodically, or randomly, or may have sub-wavelength-sized features that are arranged periodically, quasi-periodically, or randomly. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In some embodiments, the outcoupling layer is placed only over plasmonic sub-pixels, while in other embodiments the outcoupling layer is placed over all the sub-pixels. In some embodiments the outcoupling layer is placed over a portion of the sub-pixels in the display.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from 40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments the display is a microOLED display that is less than 2 inches diagonal. In some embodiments, the OLED is a display panel having at least 10 inch diagonal or 50 square inch area. In some embodiments, the OLED is a lighting panel. In some embodiments, the OLED display may have a pixel size that is less than 100 micrometers. In some embodiments, at least one of the sub-pixels within the pixel may be less than 20 micrometers in the smallest dimension within the plane of the pixels. In some embodiments, at least one of the sub-pixels within the pixel may be less than 5 micrometers in the smallest dimension within the plane of the pixels.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes, such as phosphor sensitized fluorescence.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below. Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Embodiments described herein may be found in devices that have pixels that include one or more sub-pixels. In a first embodiment, at least one of the sub-pixels may be in a side-by-side (SBS) architecture. In a SBS architecture, at least one or more emissive layers of each sub-pixel the pixel are different than another sub-pixel in the pixel. Generally, a “Red” sub-pixel will have a red emissive layer and the red emissive layer emits red light and the sub-pixel emits red light. In an embodiment, there may be no color filter or color altering layer in a SBS architecture, although this is not a requirement and a color filter or color altering layer may be used. In a second embodiment, at least one of the sub-pixels may be in a stacked architecture. In a stacked architecture, at least one or more emissive layer is shared between two or more sub-pixels in the pixel. Generally, this is used in a white plus color filter/color altering layer architecture, where the emissive layers in the pixel produce “white” light and different color filter/color altering layer arrangements are used for sub-pixels in the pixel to produce a desired color. For example, the stack could produce “white”, a first sub-pixel could have a red color filter/color altering layer so the first sub-pixel would produce red light and a second sub-pixel could have a green color filter/color altering layer so the second sub-pixel would produce green light. Any color filtering/altering may be used to produce any color light. Additionally, the stack does not necessarily need to produce a “white” light and can produce any color light. Devices may be made that are a mixture of both SBS and stack architecture to produce pixel/sub-pixel design that includes some or all of the architectures described. Embodiments of the present invention may include one or more of a SBS or stacked pixel/sub-pixel design.

Plasmonic OLEDs may have great benefits from reduced excited state lifetimes. This may lead to extended operational lifetimes, along with increased external quantum efficiency (EQE) that may enable higher luminance and stable OLED devices. Such devices may have Lambertian emission profiles. The optical performance of a device may benefit from the photons being generated outside the organic stack by an outcoupling layer (i.e., a nanoparticle-based outcoupling scheme (NPO)). The outcoupling layer may include one or more outcoupling layers, such as a dielectric spacer, a material layer that has nanoparticles, one or more nanoparticles, and the like. While this arrangement may allow for high EQE and Lambertian emission, it may make it difficult to employ cavity optics for highly saturated emissive colors, particularly for blue. In some embodiments, the angular dependence of color shift and/or intensity may vary between sub-pixels. In some embodiments, the sub-pixel with the plasmonic stack may have the least variation in intensity with angle. In some embodiments, the sub-pixel with the plasmonic stack may have the least variation in color with angle. In some embodiments, the green sub-pixel may have the least variation in one of the intensity or color shift with angle. In an embodiment, the green sub-pixel may have the largest influence on the luminance level as a function of angle. Additionally, all sub-pixel light emission may contribute to the color variation observed as a function of angle. However, in an all-blue image, the blue subpixel, when the display is showing only blue, may have the least perceptible shift in (blue) color with angle due to the sensitivity of the eye.

Embodiments of the disclosed subject matter may provide display architectures that combine plasmonic and cavity sub-pixels (e.g., blue cavity sub-pixel) in the same display to improve efficiency and/or lifetime of a device, as well as improve a display viewing angle. Embodiments of the disclosed subject matter recognize that a cavity sub-pixel may be one or more of selected from the group consisting of: a top emission (TE) sub-pixel or a bottom emission (BE) sub-pixel. Herein, a BE sub-pixel emits light through the substrate while, alternatively, a TE sub-pixel emits light without going through the substrate. Alternatively, a BE or TE sub-pixel may not be a cavity sub-pixel.

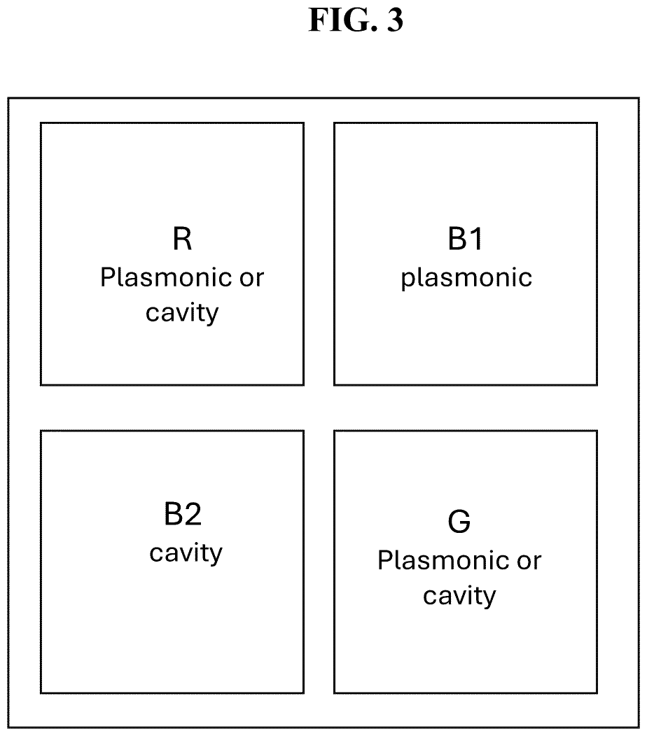

FIG. 3 shows a schematic diagram for a RGB1B2 architecture, in which a R sub-pixel is configured to output red light, a G sub-pixel is configured to output green light, a B1 sub-pixel is configured to output light blue light, and a B2 sub-pixel is configured to output deep blue light. The light blue sub-pixel may be a plasmonic device, and the red and/or green sub-pixels may be plasmonic devices, cavity structures, and/or non-cavity devices. The B2 deep blue sub-pixel may be a cavity device.

In one embodiment of the disclosed subject matter, a plasmonic device may be combined with a RGB1B2 device architecture, where the B1 light blue emission may use a plasmonic device for at least a portion of the blue emission, and the B2 deep blue emission (when needed) may be produced from a cavity device. The B2 cavity device may be used for a small percentage of operating time, which may make the lifetime and efficiency parameters of the device less stringent. Most blue light emission may be provided by the B1 plasmonic device where device lifetime, EQE, and emission profile benefit from plasmonic enhancement. Red and/or green sub-pixels in this example device architecture may be cavity or non-cavity structures, or may be plasmonic devices.

In another RGB1B2 embodiment, other colors in addition to B1 (e.g., red, green, and/or yellow) may be plasmonic devices. In this example, B2 may be a cavity design, and may be either a single stack or tandem arrangement. This arrangement may provide displays with improved viewing angles. In alternative embodiments, the display may include any number of multiple color pixel arrangements. In other words, the display may be an R1R2 GB, RG1G2B, R1R2G1G2B or R1R2G1G2B1B2 RG1G2B1B2, or the like arrangements. In these arrangements, there may be any combination of plasmonic and non-plasmonic sub-pixels. For example, the common color sub-pixels (i.e., R1R2, G1G2, or B1B2) may both be plasmonic, may both be non-plasmonic, or one may be plasmonic and one may be non-plasmonic. Unrelated to that arrangement, the non-common color sub-pixels (i.e., the G and B in the R1R2 GB, the R and G in the RGB1B2, the R and B in RG1G2B, or the like) may be any mixture of plasmonic and non-plasmonic sub-pixels. For example, in a R1R2 GB arrangement, the G may be a plasmonic sub-pixel and B may be a non-plasmonic sub-pixel. Alternatively, in a R1R2 GB arrangement, the G and B may be both plasmonic sub-pixels or may both be non-plasmonic sub-pixels.

It should also be noted, in some embodiments, the number of sub-pixels that are the same color may not be limited to two, as there may be 3 or more sub-pixels of the same color (e.g., RGB1B2B3).

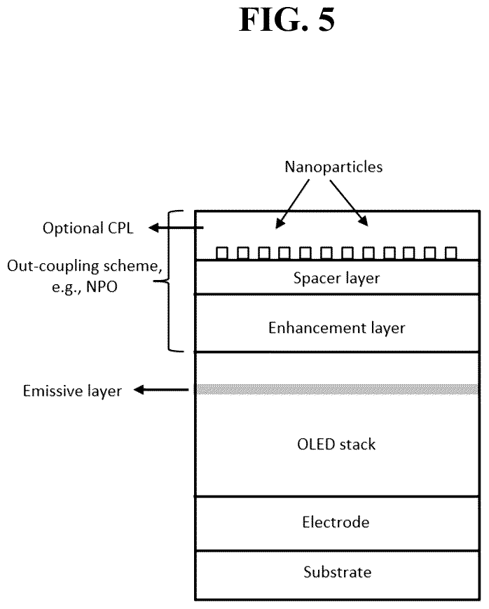

To simplify manufacturing, a single nanoparticle size may be chosen to out-couple plasmon energy from both the red and green sub-pixels. The specific out-coupling resonance (i.e., color) may be tuned by having dielectric spacer materials with different refractive index values for the red and green sub-pixels. In one embodiment, the refractive index of the spacer layer for the red sub-pixel may be higher than the refractive index of the spacer layer for the green sub-pixel. In another embodiment, the red and green sub-pixels may use the same dielectric spacer layer material, but the nanoparticles for one of the sub-pixels (e.g., the red sub-pixel) may be overcoated with a dielectric material, such as a capping layer (CPL, such as shown in FIG. 5), that has higher refractive index than any dielectric material that may overcoat the green sub-pixel, as shown in the plasmonic PHOLED sub-pixel stack of FIG. 5. This may have the effect of red shifting the NPO resonance to gain good spectral overlap with the emission spectrum of an emitter device. The refractive index of the CPL and/or the thickness of the CPL may be varied to tune the plasmon out-coupling resonance. Generally, for metal nanoparticles, higher refractive index spacer layers and CPLs may red shift the plasmon out-coupling resonance. By overcoating the nanoparticles with a CPL, the effective refractive index surrounding the particles may be changed, and may saturate around 200 nm CPL thickness. The NPO resonance may be tuned via the excess free polymer in the nanoparticle solution, with higher concentration of excess free polymer increasing the effective refractive index surrounding the nanoparticles, thereby resulting in a red shift.

In some embodiments, a capping layer may be disposed over the plasmonic sub-pixels, such as the red (R), light blue (B1), and/or green (G) sub-pixels. In some embodiments, a capping layer may be disposed over the cavity sub-pixels, such as a cavity red (R) sub-pixel, a cavity deep blue (B2) sub-pixel, and/or the cavity green (G) sub-pixel. In some embodiments, the same material may be used for capping layers for the plasmonic and cavity sub-pixels. In other embodiments, a first material may be used as a capping layer for the plasmonic sub-pixels, and a second material may be used as a capping layer for the cavity sub-pixels.

In some embodiments, when two or more of the sub-pixels are plasmonic the two or more sub-pixels that are plasmonic may have the same dielectric spacer material or may have a different dielectric spacer material. In some embodiments, when two or more of the sub-pixels are plasmonic the two or more sub-pixels that are plasmonic may have a same thickness of dielectric spacer material or may have a different thickness of dielectric spacer material. In these embodiments, the thickness may be the same or different regardless of the material chosen for the dielectric spacer material and/or the refractive index of the material chosen for the dielectric spacer material. In some embodiments, when two or more of the sub-pixels are plasmonic the two or more sub-pixels that are plasmonic may have a same refractive index of dielectric spacer material or may have a different refractive index of dielectric spacer material.

The manufacturing process may be further simplified by depositing the nanoparticles over all R, G, and B sub-pixels. This may have the effect of scattering or extracting the cavity emission of the non-plasmonic sub-pixels into a more Lambertian profile, which may be desirable for some applications. For example, if the blue sub-pixel is a TE microcavity device, and nanoparticles are deposited over all the sub-pixels, the angular dependence of the blue sub-pixel may be changed due to the nanoparticles. It may be that the nanoparticles reduce the angular dependence of the blue sub-pixel resulting in a display with improved angular dependence. In another embodiment, R, G, and B sub-pixels may share a common cathode material, composition, and/or thickness. While plasmonic devices may use a thicker Ag cathode (˜30 nm) compared to top emission micro-cavity devices (˜15 nm), the mircocavity device may be able to recover some of or even more than the light lost from the reduced transmittance of the thicker cathode with plasmon out-coupling. The common cathode may be thickness-tuned to achieve a desired combination of plasmon out-coupling efficiency and TEMC out-coupling efficiency. For example, an Ag cathode less than 30 nm thick may reduce the plasmon out-coupling efficiency of the plasmonic sub-pixels, but may increase the out-coupling efficiency via increased cathode transmittance of the TEMC sub-pixel.

In some embodiments, the same emissive layer (EML) may be used for both the B1 and B2 sub-pixels to simplify device fabrication having three (3) OLED emitter depositions for four (4) sub-pixels.

The use of light blue sub-pixels as a plasmonic device may lead to a simplified design of the outcoupling layer, as only one sized outcoupling layer nanoparticle may need to be deposited over the device cathode, and the nanoparticle size used to produce light blue emission may be easier to manufacture than the sub-pixels for deep blue emission. In some embodiments, there may be more than one size for the outcoupling layer nanoparticles.

The emissive layer of the embodiments described above may be from fluorescence, thermally activated delayed fluorescence (TADF), phosphorescence, phosphor sensitized fluorescence (PSF), an inorganic emissive material, 2D dichalcogenide emissive material, perovskites, and/or quantum dots.

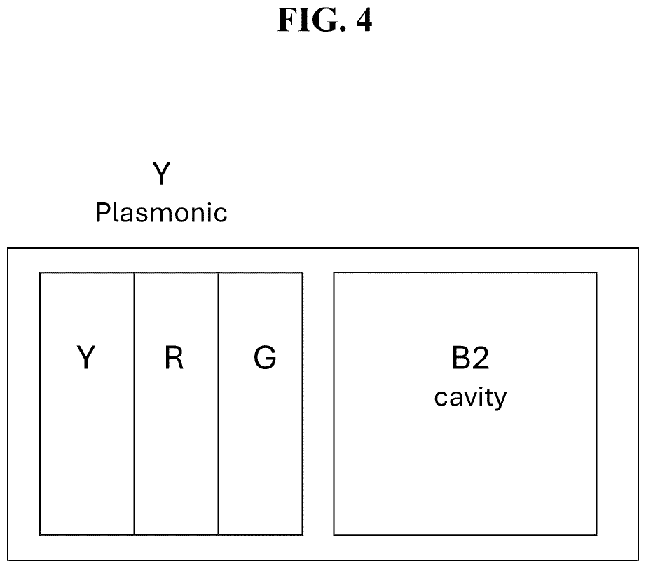

FIG. 4 shows a schematic diagram of for a YB plus CF architecture, where a Y device may be configured to emit yellow light, a R sub-pixel is configured to emit red light, a G sub-pixel is configured to emit green light, and where a B device may be configured to emit blue light, and where a B2 sub-pixel may be configured to emit deep blue light. The Y device may be a plasmonic device, and the R and/or G sub-pixels may be a plasmonic device with color altering layers over the Y device. The B2 sub-pixel may have a cavity design.

In another embodiment, a YB plus CF display architecture may be used. In this example architecture, two OLED emitter depositions (i.e., a yellow deposition and a blue deposition) may be used, and a plasmonic enhancement may be applied to the yellow devices. Color altering layers (e.g., color filters) may be used to produce yellow, green, and red Lambertian plasmonic or non-plasmonic emission. A blue sub-pixel may have a cavity arrangement. This architecture may provide a display with a very small color shift over a viewing angle. This arrangement may use a single outcoupling layer design to be fabricated over the yellow sub-pixel.

Plasmonic emission may be used to tailor the emission profile of the device to provide optimization between efficiency and an emission profile. This may enhance efficiency and/or provide low angular dependence to the output color or luminance.

In one embodiment, a three sub-pixel RGB display may be provided, where a cavity may be configured to emit blue light, a plasmonic device may be configured to emit red light, and another plasmonic device may be configured to emit green light. This arrangement may have improved efficiency and viewing angle characteristics. The blue emissive cavity may be a single stack or tandem stack to improve lifetime and/or efficiency. As DCIP3 white light is approximately composed of 94% red and green light, display efficiency may benefit from very high plasmonic EQE that may be achievable with red and green sub-pixels.

As plasmonic devices have enhanced lifetimes and reduced roll-off at higher luminance than conventional devices, the green and red sub-pixels may be driven harder to reduce their AR (aperture ratio) or fill-factor, which may enable an increase of the blue sub-pixel AR and therefore enhance blue sub-pixel lifetime. A conventional RGB architecture may have an AR of 25:25:25 (which represents the relative AR between red (R), green (G), and blue (B) sub-pixels, with the AR values notated as R:G:B), and there may be an AR of 15:15:45 using the architecture of the above-described embodiment with a cavity for a blue sub-pixel, and plasmonic sub-pixels to output red and green light. For the R:G:B:notation, all the available pixel area (e.g., assuming 100%) may be divided into active regions for the emissive areas and non-emissive areas, along with allowing for process tolerances. The maximum AR for the three colors (red, green, blue) would be 33% assuming all are equal, but they may be about 25% when process limitations are accounted for. There may be 2% or 3% reduction in red and green cd/A due to having to drive the subpixels at a higher drive current to account for reduced AR, but there may be a twofold (2×) or higher blue sub-pixel lifetime enhancement in this arrangement as the blue sub-pixel AR has been increased which is enabled by reducing the red and green AR.

In this embodiment, blue sub-pixels may have a cavity arrangement (tandem or single emissive layer) with higher AR for even higher blue lifetime and good saturated blue efficiency. This arrangement may have improved display efficiency, viewing angle, and lifetime. This arrangement may have improved manufacturability, as only one size outcoupling layer nanoparticle may be used for both red and green sub-pixels, and therefore only one size outcoupling layer nanoparticle needs to be deposited onto the display. Dielectric layers of different refractive index may be applied between the cathode and outcoupling layer for the red and green sub-pixels to optimize outcoupling layer performance for both these colors.

For COE (color filter and/or color altering layer on encapsulation) arrangements, small aperture ratios (AR) may be preferred so reflection is reduced from the display surface due to smaller sub-pixel area, and the sub-pixel active area may be reflective because of reflective electrodes used in the sub-pixel architecture. In an embodiment having plasmonic red and green sub-pixels with small AR and a blue sub-pixel having a cavity, this may benefit RGB displays if the RG aperture ratio is reduced, thus reducing reflection from the front surface of the display. This may be because the red and green sub-pixels may be driven harder due to increased plasmonic lifetime and reduced efficiency roll-off at higher luminance, to enable reducing green and red AR. The blue AR may be increased, thereby further enhancing blue lifetime. Increasing blue reflection may be expected to be much less problematic than green or red reflection due to the human eye being less sensitive to blue light than red or green light. In some embodiments when using COE for the pixels within the display, additional incorporation of nanoparticles for the sub-pixels may enable larger aperture ratios as the nanoparticles will scatter incoming ambient light into the black polymer layer between sub-pixels and between the color filters.

The red, green, and blue sub-pixel plasmonic devices may have high efficiency and Lambertian output. The red, green, and blue sub-pixel plasmonic devices may have low reflectivity from a smaller AR for a COE arrangement, based on plasmonic lifetime enhancement.

Blue sub-pixels may have a cavity arrangement (e.g., tandem or single emissive layer) with higher AR for increase blue sub-pixel lifetime and good saturated blue efficiency. Even without concern for reducing display reflectivity, embodiments of the disclosed subject matter may provide high efficiency, wide viewing angle, and/or improved lifetimes. The red and green plasmonic sub-pixels may have reduced AR, and the blue cavity (tandem) sub-pixels may have increased AR.

In some embodiments, a capping layer may be disposed over the plasmonic sub-pixels, such as the yellow (Y), red (R), and/or green (G) green sub-pixels shown in FIG. 4. In some embodiments, a capping layer may be disposed over the cavity sub-pixels, such as a cavity deep blue (B2) sub-pixel shown in FIG. 4. In some embodiments, the same material may be used for capping layers for the plasmonic and cavity sub-pixels. In other embodiments, a first material may be used as a capping layer for the plasmonic sub-pixels, and a second material may be used as a capping layer for the cavity sub-pixels.

The embodiments described above may provide a plurality of advantages over conventional architectures. The embodiments may provide improved viewing angle with Lambertian emission for red and green sub-pixels. Lower display reflectivity red and green sub-pixels in the embodiments of the disclosed subject matter may provide a smaller AR for a COE polarizer-free arrangement, assuming that blue reflection is less problematic than red or green reflection. Blue sub-pixel lifetime in the embodiments of the disclosed subject matter may be enhanced by increasing the AR of the blue sub-pixels, as the enhanced lifetime of plasmonic red and green sub-pixel means that their AR may be decreased. The 25:25:25 AR using an architecture of a conventional device may be improved to an AR of 15:15:45 (for R:G:B) using an arrangement one of the embodiments of the disclosed subject matter as discussed above. There may be a 2% or 3% reduction in red and green sub-pixel cd/A due to higher drive current to compensate for reduced RG AR, but there may be twofold (2×) or larger increase in blue sub-pixel lifetime enhancement. The embodiments of the disclosed subject matter may increase manufacturability, as only one size outcoupling layer nanoparticle may be used and dielectric layers of different refractive index may be applied between the cathode and outcoupling layer nanoparticle for red and green sub-pixels to optimize outcoupling layer nanoparticle performance for both of these colors.

In some embodiments, a display architecture may include Purcell blue sub-pixel device with plasmonic red and green sub-pixels. The Purcell blue sub-pixel may be a polariton-enhanced Purcell (PEP) effect device. In some embodiments, devices may use the PEP effect to extend the operational lifetime of PHOLEDs, such a blue, red, green, and/or white PHOLEDS. Energy transfer to PEPs significantly reduces the triplet radiative lifetime and their density within the PHOLED emission layer (EML). PEPs are a strongly coupled state at the metal/dielectric interface resulting from mixing of the SPP mode of the metal with excitons in the adjacent dielectric layer(s). Here, the PEP strength is a function of the oscillator strengths of both the cathode and electron transport layer (ETL). Combined with a low-quality factor (Q) optical cavity comprising an Ag cathode and a distributed Bragg reflector (DBR) mirror, the light extraction efficiency and the emission color saturation are increased. In some examples, a portion of the ETL absorption spectrum such as the long wavelength tail (i.e. imaginary part of index of refraction) is in the emission spectrum of the EML. In some embodiments, the polariton is detuned from absorption. In some embodiments, the ETL absorption spectrum (or the imaginary part of index of refraction) is higher than (i.e. shorter wavelength) the emission spectrum of the EML, instead in the EML emission spectrum. In some embodiments, the polariton is detuned to overlap with the EML emission to enhance the Purcell effect, instead of detuning from the absorption. In some embodiments, this overlap can be tuned to balance light extraction and absorption. In some embodiments, inefficient triplets are encouraged to radiate into polaritons.

In some embodiments, a display architecture may include PEP device for any number of the sub-pixels, disclosed in U.S. Patent Application Publication No. 2024/0268139, which is incorporated by reference in its entirety. Embodiments of the disclosed subject matter may provide a display in which some of the sub-pixels have different angular dependence than the other sub-pixels. This arrangement differs from that of current displays, which use the same device structure for all the sub-pixels. For example, mobile phones typically utilize a top emitting microcavity OLED structure to achieve narrow emission with a forward-going angular profile. As user interaction with the display is gaining in importance, it may be beneficial to change the angular dependence of the sub-pixel or sub-pixels that have the largest impact on color shift with angle. For example, the green sub-pixel of a top emitting microcavity device may exhibit the most noticeable loss of intensity and change in color compared to the blue and red sub-pixels. Thus, if the green sub-pixel was a plasmonic device or even a top emitting non-microcavity OLED, then the overall display may have less color shift with angle.

In some embodiments, plasmonic and top emission cathodes may be fabricated in the same display. A top emission (TE) cathode and a plasmonic cathode may be used on the same display. For example, the same thin Ag cathode may be used for both top emission devices and plasmonic devices. Typically, plasmonic and top emission cathodes differ in both their thickness (about 30 nm for plasmonic, and about 15 nm for TEMC) and their composition (e.g., pure Ag for plasmonic, and Ag:Mg for TEMC). If both plasmonic and TEMC sub-pixels are used, the same cathode (i.e., the same thickness and material composition) may reduce manufacturing complexity.

In some embodiments, a cathode patterning technique (e.g., such as developed by OTI Lumionics, Inc.) may be applied to selectively deposit additional cathode material over regions requiring additional cathode metal after blanket deposition of thin silver.

Hybrid displays with both plasmonic and cavity devices may be fabricated. To simplify manufacturing, a single nanoparticle size could be chosen to out-couple plasmon energy from both the red and green sub-pixels. The specific out-coupling resonance (color) can be tuned by choosing dielectric spacer materials with different refractive index values for the red and green sub-pixels. In a preferred embodiment, the refractive index of the spacer layer for the red sub-pixel will be higher than the refractive index of the spacer layer for the green sub-pixel. In a separate preferred embodiment, the red and green sub-pixels may utilize the same dielectric spacer layer material, but the nanoparticles for one of the sub-pixels, preferably the red sub-pixel, could be overcoated with a dielectric material, like a capping layer (CPL), that has higher refractive index than any dielectric material that may overcoat the green sub-pixel, see FIG. 3. This will have the effect of red shifting the outcoupling layer nanoparticle resonance to gain good spectral overlap with the emitter's spectrum. The refractive index of the CPL and/or the thickness of the CPL can be varied to tune the plasmon out-coupling resonance. Generally, for metal nanoparticles, higher refractive index spacer layers and CPLs will redshift the plasmon out-coupling resonance. By overcoating the nanoparticles with a CPL, the effective refractive index surrounding the particles is changed, and will saturate around 200 nm CPL thickness. The outcoupling layer nanoparticle resonance may also be tuned via the excess free polymer in the nanoparticle solution, with higher concentration of excess free polymer increasing the effective refractive index surrounding the nanoparticles, thereby resulting in a redshift.

The manufacturing process may be further simplified by depositing the nanoparticles over all R, G, and B sub-pixels. This may have the effect of scattering or extracting the cavity emission of the B sub-pixel into a more Lambertian profile, which may be desirable for some applications. In another preferred embodiment, R, G, and B sub-pixels share a common cathode material, composition, and thickness. While plasmonic devices typically use a thicker Ag cathode (˜30 nm) compared to TEMC devices (˜15 nm), the TEMC device may be able to recover some of or even more than the light lost from the reduced transmittance of the thicker cathode with plasmon out-coupling. The common cathode may be thickness-tuned to achieve a desired combination of plasmon out-coupling efficiency and TEMC out-coupling efficiency. For example, an Ag cathode less than 30 nm thick may reduce the plasmon out-coupling efficiency of the plasmonic sub-pixels, but may increase the out-coupling efficiency, via increased cathode transmittance, of the TEMC sub-pixel.

If one or more subpixels combine a TEMC with plasmonic outcoupling, the distance from the EML to the cathode may be used to tune the fraction of light output with either “cavity” (forward going) character or “plasmonic” (Lambertian) character. The farther away from the enhancement layer, the less plasmonic and more cavity-like the output of the light will be. For some example ranges, if the midpoint of the EML to the enhancement layer is <25 nm, the emission will be mostly plasmonic, while for greater distances, the emission will be mostly cavity-like. For manufacturing ease, it may be advantageous to make all subpixels TEMC plus a plasmonic outcoupling. In a full color display, pixels capable of producing white light will generally have three or more sub-pixels. These sub-pixels could be either cavity, bottom emission or plasmonic as well as subpixels that combine both cavity and plasmonic emission. We define a plasmonic subpixel as one where the enhancement layer is less than a threshold distance from the organic emissive layer, and a subpixel that combines both cavity and plasmonic emission as one where the enhancement layer is greater than a threshold distance from the organic emissive layer and also contains an outcoupling layer where the outcoupling layer scatters or extracts the energy from the surface plasmon polaritons as photons emitted from the device.

As described above, a plasmonic stack may include an enhancement layer having a plasmonic material exhibiting surface plasmon resonance that non-radiatively couples to the organic emissive material and transfers excited state energy from the emissive material to non-radiative mode of surface plasmon polaritons, disposed over the organic emissive layer opposite from the first electrode, and an organic emissive layer having an organic emissive material disposed over the electrode, the organic emissive material having a total non-radiative decay rate constant and a total radiative decay rate constant due to the presence of the enhancement layer. The enhancement layer may be provided no more than a threshold distance away from the organic emissive layer, and in a first embodiment the threshold distance being a distance at which the total non-radiative decay rate constant is equal to the total radiative decay rate constant.

Also as described above, a plasmonic stack may include an organic emissive layer having an organic emissive material disposed over the electrode, where the organic emissive material may have a total non-radiative decay rate constant

$${k}_{n o n - r ad}^{0} ,$$

a total radiative decay rate constant

$${k}_{ra d}^{0} ,$$

a total non-radiative decay rate constant due to the enhancement layer

$${k}_{non - r ad}^{plasmon} ,$$

and may have a total radiative decay rate constant due to the enhancement layer

$${k}_{r ad}^{plasmon} .$$

The plasmonic stack ma include an enhancement layer having a plasmonic material exhibiting surface plasmon resonance that non-radiatively couples to the organic emissive material and transfer excited state energy from the emissive material to non-radiative mode of surface plasmon polaritons, disposed over the organic emissive layer opposite from the first electrode. The enhancement layer may be provided no more than a threshold distance away from the organic emissive layer, where the threshold distance may be a distance at which

$$\frac{{k}_{r ad}^{plasmon}}{{k}_{non - r ad}^{plasmon}} = \frac{{k}_{ra d}^{0}}{{k}_{non - ra d}^{0}} .$$

More generally, the formula above is a simplification of a simple to understand condition, that is, where the photon yield (also known as photoluminescent quantum yield) in the presence of enhancement layer is the same as the photon yield of the emissive material. To put it simply,

$$Photon {yield}^{0} = \frac{{k}_{rad}^{0}}{{k}_{rad}^{0} + {k}_{non - rad}^{0}} ,$$

where the material is in vacuum. Upon placing a material near an enhancement layer, the material can experience increases in both radiative and non-radiative rate constants.

$$Photon yield = \frac{{k}_{rad}^{total}}{{k}_{rad}^{total} + {k}_{non - rad}^{total}} = \frac{{k}_{rad}^{0} + {k}_{rad}^{plasmon}}{{k}_{rad}^{0} + {k}_{rad}^{plasmon} + {k}_{non - rad}^{0} + {k}_{non - rad}^{plasmon}}$$

Solving for the case where the photon yield in the presence of the enhancement layer is the same as the photon yield in vacuum yields the following:

$$\frac{{k}_{rad}^{0}}{{k}_{rad}^{0} + {k}_{non - rad}^{0}} = \frac{{k}_{rad}^{0} + {k}_{rad}^{plasmon}}{{k}_{rad}^{0} + {k}_{rad}^{plasmon} + {k}_{non - rad}^{0} + {k}_{non - rad}^{plasmon}}$$

Which can be simplified to this condition:

$$\frac{{k}_{rad}^{plasmon}}{{k}_{non - rad}^{plasmon}} = \frac{{k}_{rad}^{0}}{{k}_{non - rad}^{0}} .$$

The TEMC subpixel may further have its angular dependence modified by the CPL. TEMC devices with CPLs thinner than the optimized thickness that achieves maximum forward brightness can result in an emission profile that is more Lambertian. Meanwhile, the cavity thickness itself, as determined by the organic layer thicknesses stacked between the reflecting mirrors, largely determines the narrowness of the emission spectrum, which affects the color point. While the CPL thickness may be zero and result in a device that does not have the typical forward-going angular profile of TEMC OLEDs, there may be a desired CPL thickness, which may depend on the refractive index of the CPL, that achieves a desired close-to-Lambertian emission profile while optimizing for a desired outcoupling value (EQE, luminance, etc.) at a given angle, which may be normal incidence.

As described above in connection with FIGS. 3-5, a device may include a full color organic light emitting diode (OLED) having a plurality of pixels, where each pixel has a plurality of sub-pixels. A first pixel of the plurality of pixels may include a first sub-pixel having a top emission device or a bottom emission device, and a second sub-pixel having a first plasmonic stack. For the first pixel, a third sub-pixel may include a structure of a cavity, a plasmonic stack, and/or a bottom-emission device. The top emission device may be a cavity structure.

The first plasmonic stack may include an organic emissive layer having an organic emissive material disposed over the electrode, where the organic emissive material has a total non-radiative decay rate constant

$${k}_{non - rad}^{0} ,$$

a total radiative decay rate constant

$${k}_{rad}^{0} ,$$

a total non-radiative decay rate constant due to the enhancement layer

$${k}_{non - rad}^{plasmon} ,$$

and a total radiative decay rate constant due to the enhancement layer

$${k}_{rad}^{plasmon} .$$

The first plasmonic stack may include an enhancement layer (e.g., the enhancement layer shown in FIG. 5) having a plasmonic material exhibiting surface plasmon resonance that non-radiatively couples to the organic emissive material and transfer excited state energy from the emissive material to non-radiative mode of surface plasmon polaritons, disposed over the organic emissive layer opposite from the first electrode. The enhancement layer may be provided no more than a threshold distance away from the organic emissive layer, where the threshold distance is a distance at which

$$\frac{{k}_{rad}^{plasmon}}{{k}_{non - rad}^{plasmon}} = \frac{{k}_{rad}^{0}}{{k}_{non - rad}^{0}} .$$

The first plasmonic stack may include an outcoupling layer (e.g., as shown in FIG. 5) disposed over the enhancement layer, where the outcoupling layer scatters or extracts the energy from the surface plasmon polaritons as photons to free space.

In some embodiments, the outcoupling layer may be disposed over all sub-pixels of the first pixel. In other embodiments, the outcoupling layer may be disposed over only one or more sub-pixels in the first pixel.

When the first pixel is capable of emitting white light at a DCIP3 white point, greater than 1%, greater than 3%, greater than 5%, greater than 10%, greater than 25%, or greater than 50% of photons of light emitted by the first pixel may be emitted from a plasmon mode of the first sub-pixel. Greater than 1%, greater than 5%, greater than 10%, greater than 15%, greater than 20%, or greater than 25% of an absolute EQE of the first pixel may be attributable to emission from a plasmon mode of the first sub-pixel. Greater than 1%, greater than 5%, greater than 10%, greater than 15%, greater than 20%, or greater than 25% of the EQE of the OLED when rendering a uniform D65 white point image may be attributable to emission from a plasmon mode.

In some embodiments, the first plasmonic stack may include a color altering layer disposed over the outcoupling layer, where there is an overlap between a transmission spectrum of the color altering layer and an emission spectrum of light output from the outcoupling layer. The color altering layer may be a color filter, quantum dots, other thin film technologies that can modify the spectrum of light passing through the layer, or the like. The enhancement layer may be an electrode of the plasmonic stack.

In some embodiments, the first plasmonic stack may include an enhancement layer having a plasmonic material exhibiting surface plasmon resonance that non-radiatively couples to the organic emissive material and transfer excited state energy from the emissive material to non-radiative mode of surface plasmon polaritons, disposed over the organic emissive layer opposite from the first electrode, and an organic emissive layer having an organic emissive material disposed over the electrode, the organic emissive material having a total non-radiative decay rate constant and a total radiative decay rate constant due to the presence of the enhancement layer. In some embodiments, the enhancement layer may be provided no more than a threshold distance away from the organic emissive layer. The threshold distance may be a distance at which the total non-radiative decay rate constant is equal to the total radiative decay rate constant.

In some embodiments, the first sub-pixel of the device may include an emissive material configured to emit blue light and/or deep blue light, and the second sub-pixel may be configured to emit yellow light. In some embodiments, at least one of the first and second sub-pixels may include a color altering layer.

In some embodiments, the first pixel may include at least three sub-pixels, and where each of the at least three sub-pixels, other than the sub-pixel having the material configured to emit deep blue light, may be configured to emit green light or red light. At least one of the at least three sub-pixels may be configured to emit green light. At least one of the at least three sub-pixels may be configured to emit red light.

In some embodiments, the first pixel may include at least four sub-pixels. At least one of the at least four sub-pixels, other than the sub-pixel having the material configured to emit deep blue light or light blue light, may include a color altering layer configured to emit yellow light, green light, or red light. At least one of the at least four sub-pixels may be configured to emit green light. At least one of the at least four sub-pixels is configured to emit red light. Two sub-pixels of the at least four sub-pixels may have a same emissive layer. The first sub-pixel may be configured to emit deep blue light or light blue light, and the at least one other sub-pixel of the at least four sub-pixels is configured to emit deep blue light or light blue light.

In some embodiments, the first pixel of the device may include at least three sub-pixels, and the first pixel may include an outcoupling layer that outcouples light from at least one of the at least three sub-pixels. The outcoupling layer may emit yellow light, and each of the three or more sub-pixels may have a color altering layer configured to emit yellow, green, or red light. For example, one of the at least three sub-pixels of the device may be configured to emit green light, and one of the at least three sub-pixels may be configured to emit red light. The outcoupling layer may be patterned over each of the plurality of sub-pixels that are plasmonic, and not patterned over each of the plurality of sub-pixels that are not plasmonic. The device of this embodiment may include not more than two emissive layer depositions. The two emissive depositions may include yellow and blue emissive materials. In some embodiments, the device may include not more than three emissive layer depositions.

In some embodiments, the two sub-pixels of the first pixel of the device may be configured to emit light having a same first color. The two sub-pixels may be the first sub-pixel and the second sub-pixel.

The first plasmonic stack of the device may include a plurality of nanoparticles, such as shown in FIG. 5, having an average nanoparticle size. Each plasmonic sub-pixel in the first pixel may include nanoparticles having a size coefficient variation of not more than 15%. In some embodiments, each plasmonic sub-pixel in the device may include nanoparticles having a size coefficient variation of not more than 15%. In some embodiments, the nanoparticles may have a size coefficient of variation of less than 15%, more preferably less than 10%, and more preferably less than 5%. In some embodiments, the size variation of the nanoparticles is less than 25% or less than 15%. In embodiments where there is a single nanoparticle deposition but over two different-colored sub-pixels (e.g., red and green sub-pixels), then it may be desirable to have a larger size variation to broaden the out-coupling resonance (i.e., broaden the wavelength of the emission spectrum from the nanoparticles). In this case, the coefficient of size variation of the nanoparticles may be, for example, 35-50%.

The plurality of nanoparticles may have maximum diameters that vary by not more than 70 nm from each other. If one or more of the nanoparticles have variation in their shape, the maximum diameter may vary by not more than 20% in size from each other. All nanoparticles disposed over plasmonic sub-pixels in the device may have maximum diameters that vary by not more than 70 nm from each other. The nanoparticle size may be selected to out-couple plasmon energy from the first plasmonic stack, where the plasmonic stack may be configured to emit red light and/or green light. The plasmonic stack may include a dielectric spacer material having a refractive index selected based on a color of light emitted by the organic emissive material. The second sub-pixel of the device may be configured to emit red light or green light.

The nanoparticles may be coated with a dielectric material. In some embodiments, the dielectric material may be a capping layer (CPL). The nanoparticles may be coated with a dielectric material, usually a polymer, to improve colloidal stability. In other embodiments, dielectric shells may be grown around the nanoparticles, such as when the nanoparticles are formed from metal. In some embodiments, the device may include a capping layer disposed over the plasmonic stack. In some embodiments, a capping layer may be disposed over the non-plasmonic sub-pixels (e.g., the cavity sub-pixels, such as those shown in FIGS. 3-4). The capping layer may be the same material to cover the plasmonic stack (i.e., the plasmonic sub-pixels) and non-plasmonic subpixels. In some embodiments, a first material may be used for a capping layer disposed over the plasmonic stack and/or plasmonic sub-pixels, and a second material may be used for a capping layer disposed over the non-plasmonic subpixels (e.g., the cavity sub-pixels, such as those shown in FIGS. 3-4).

The plasmonic stack may include a dielectric spacer material, where the dielectric material may have a refractive index selected based on a color of light emitted by the organic emissive material. The dielectric spacer material in each plasmonic sub-pixel may have a spacer size that varies by not more than 10%. Each plasmonic sub-pixel in the device may include a dielectric spacer material having a spacer size that varies by not more than 50%. For each sub-pixel, the spacer layer thickness layer variation may approach zero or be zero, as the variation may alter the outcoupling resonance. In an example, the spacer layer thickness from the red to green sub-pixels may not vary more than 50%.

In some embodiments, the first pixel of the device may include a third sub-pixel. The first sub-pixel may be configured to emit blue light, the second sub-pixel is configured to emit red light, and a third sub-pixel may include a second plasmonic stack and is configured to emit green light. An aperture ratio of the first sub-pixel may be larger than the aperture ratios for the second sub-pixel and the third sub-pixel. The aperture ratio for the first sub-pixel of the device may be greater than 40%, greater than 50%, or greater than 60%, and the aperture ratio for the second sub-pixel, the third sub-pixel, or both is less than 20%, less than 15%, or less than 10%. The cavity structure of the first sub-pixel may be a polariton enhanced Purcell effect device.

The second sub-pixel of the device may include an outcoupling layer (e.g., a nanoparticle-based outcoupling (NPO) scheme). The nanoparticle-based outcoupling layer may include a first nanopatch antenna (NPA) array. The first NPA array may be disposed over a first dielectric material. The first sub-pixel may be configured to emit blue light, the second sub-pixel is configured to emit red light, and the third sub-pixel may include at least one structure that is a third cavity structure or bottom emission structure configured to emit green light, and/or a third plasmonic stack configured to emit green light. The first pixel may include a fourth sub-pixel having at least one structure that may be a cavity structure or bottom emission structure configured to emit yellow light or may be a plasmonic stack configured to emit yellow light.

In some embodiments, the fourth sub-pixel may have at least one structure that is a cavity structure configured to emit blue light having a first peak wavelength, and/or a second plasmonic stack configured to emit blue light having the first peak wavelength. In this embodiment, the first sub-pixel may be configured to emit blue light having a second peak wavelength different from the first peak wavelength, the second sub-pixel may include at least one structure that is a third cavity stack or bottom emission stack configured to emit red light, and/or a second plasmonic stack is configured to emit red light. In some embodiments, the third sub-pixel may include at least one structure that is a fourth cavity stack or bottom emission stack configured to emit green light, and/or a third plasmonic stack configured to emit green light.

In some embodiments, the first pixel may include a fourth sub-pixel configured to emit green light and having a structure that is a cavity, a plasmonic device, and/or a bottom-emission device. In this embodiment, the first sub-pixel may be configured to emit blue light having a first peak wavelength, the second sub-pixel may be configured to emit blue light having a second peak wavelength different from the first peak wavelength, and the third sub-pixel may be configured to emit red light from a structure that is a cavity structure, a plasmonic device, and/or a bottom-emission device.

In some embodiments, the first pixel may include a fourth sub-pixel configured to emit green light from a second plasmonic stack, a fifth sub-pixel configured to emit blue light from a second cavity structure, and a sixth sub-pixel configured to emit blue light from a third plasmonic stack. The first sub-pixel may be configured to emit red light, the second sub-pixel may be configured to emit red light, and the third sub-pixel may be configured to emit green light from a third cavity structure.

In some embodiments, the first sub-pixel of the device may have a different angular emission profile that the second sub-pixel. For example, an intensity versus an angle of light emitted may be different and/or a color shift versus an angle of light emitted may be different.

An aperture ratio of the first sub-pixel of the device may be larger than the aperture ratio of the second sub-pixel. For example, the aperture ratio for the first sub-pixel may be greater than 40%, greater than 50%, or greater than 60%, and the aperture ratio for the second sub-pixel may be less than 20%, less than 15%, or less than 10%.

In some embodiments, the first pixel may include a sub-pixel having an emissive material that is a fluorescent emissive material, a phosphorescent emissive material, a thermally activated delayed fluorescent (TADF) emissive material, a phosphor sensitized fluorescent (PSF) emissive material, 2D dichalcogenide emissive material, and/or an inorganic emissive material system. At least one sub-pixel in the first pixel may include a tandem device.

In some embodiments, the first pixel may include two or more sub-pixels that have the same emissive material, where the two or more sub-pixels are configured to emit the same color light at different peak wavelengths from each other.

In some embodiments, the second sub-pixel that is plasmonic may be configured to emit blue light, and the first sub-pixel that is top-emitting or bottom emitting may be configured to emit red light, and/or green light.

In other embodiments, the second sub-pixel that is plasmonic may be configured to emit blue light and/or green light, and the first sub-pixel that is top emitting or bottom emitting may be configured to emit red light.

In another embodiment, the second sub-pixel that is plasmonic may be configured to emit blue light and/or red light, and the first sub-pixel that is top emitting or bottom emitting may be configured to emit green light.

In yet another embodiment, the second sub-pixel that may be plasmonic may be configured to emit green light, and the first sub-pixel that is top emitting or bottom emitting may be configured to emit red light and/or blue light.

In some embodiments, the second sub-pixel that is plasmonic may be configured to emit green light and/or red light, and the first sub-pixel that is top emitting or bottom emitting may be configured to emit blue light.

In some embodiments, the second sub-pixel that is plasmonic may be configured to emit red light, and the first sub-pixel that is top emitting or bottom emitting may be configured to emit green light and/or blue light.

The plasmonic stack of the second sub-pixel of the device may include an emitter having fluorescent material, which may be configured to emit blue light.

According to an embodiment, the device may include a full color organic light emitting diode (OLED) having a plurality of pixels, where each pixel includes a plurality of sub-pixels. At least one sub-pixel of the plurality of sub-pixels may be configured differently from the other sub-pixels by a different angular emission profile, and/or a different cathode material. An angular emission profile may be where at least one sub-pixel having a microcavity configured for direct emission such that a first ratio of light from the direct emission sub-pixel in a cone having an angle of 0-20° in a normal direction relative to an overall light emission from the direct emission sub-pixel that may be at least 10%, at least 20%, and/or at least 30% higher than a second ratio of light from the Lambertian emission sub-pixel in a cone having an angle of 0-20° in a normal direction relative to an overall light emission from the Lambertian sub-pixel.

According to an embodiment, a device may include a full color organic light emitting diode (OLED) having a plurality of pixels, wherein each pixel has a plurality of sub-pixels, where, for a first pixel of the plurality of pixels a first sub-pixel comprises a top emission device or a bottom emission device or a plasmonic stack where an enhancement layer may be provided less than a threshold distance away from the organic emissive layer, and a second sub-pixel comprises a stack that has both cavity-like and plasmonic emission. The top emission device may be a cavity structure. The enhancement layer in this sub-pixel is provided more than a threshold distance away from the organic emissive layer, where the threshold distance is a distance at which

$$\frac{{k}_{rad}^{plasmon}}{{k}_{non - rad}^{plasmon}} = \frac{{k}_{rad}^{0}}{{k}_{non - rad}^{0}} .$$

The second sub-pixel includes may include an outcoupling layer, where the outcoupling layer scatters or extracts the energy from the surface plasmon polaritons as photons emitted from the device.

In some embodiments, the distance between the enhancement layer and the emissive material in the organic emissive layer may be the same for each sub-pixel and/or pixel. In some embodiments, the distance between the enhancement layer and the emissive material in the organic emissive layer may include at least one distance that is different between each sub-pixel and/or pixel.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
a full color organic light emitting diode (OLED) having a plurality of pixels, wherein each pixel has a plurality of sub-pixels, wherein, for a first pixel of the plurality of pixels:
a first sub-pixel comprises a top emission device or a bottom emission device, and
a second sub-pixel comprises a first plasmonic stack.

2. The device of claim 1, wherein the top emission device is a cavity structure.

3. The device of claim 1, wherein, for the first pixel, there is a third sub-pixel that comprises a structure that is at least one selected from a group consisting of: a cavity, a plasmonic stack, and a bottom-emission device.

4. The device of claim 1, wherein the first plasmonic stack comprises:
an organic emissive layer comprising an organic emissive material disposed over the electrode, wherein the organic emissive material has a total non-radiative decay rate constant
$${k}_{non - rad}^{0} ,$$
a total radiative decay rate constant
$${k}_{rad}^{0} ,$$
a total non-radiative decay rate constant due to the enhancement layer
$${k}_{non - rad}^{plasmon} ,$$
and a total radiative decay rate constant due to the enhancement layer
$${k}_{rad}^{plasmon} ;$$
and
an enhancement layer, comprising a plasmonic material exhibiting surface plasmon resonance that non-radiatively couples to the organic emissive material and transfer excited state energy from the emissive material to non-radiative mode of surface plasmon polaritons, disposed over the organic emissive layer opposite from the first electrode;
wherein the enhancement layer is provided no more than a threshold distance away from the organic emissive layer, wherein the threshold distance is a distance at which
$$\frac{{k}_{rad}^{plasmon}}{{k}_{non - rad}^{plasmon}} = \frac{{k}_{rad}^{0}}{{k}_{non - rad}^{0}} .$$

5. The device of claim 4, the first plasmonic stack further comprising an outcoupling layer disposed over the enhancement layer, wherein the outcoupling layer scatters or extracts the energy from the surface plasmon polaritons as photons to free space.

6. The device of claim 5, wherein the outcoupling layer is disposed over all sub-pixels of the first pixel.

7. The device of claim 5, wherein the outcoupling layer is disposed over only one or more sub-pixels in the first pixel.

8. The device of claim 5, the first plasmonic stack further comprising a color altering layer disposed over the outcoupling layer, wherein there is an overlap between a transmission spectrum of the color altering layer and an emission spectrum of light output from the outcoupling layer.

9. (canceled)

10. The device of claim 1, wherein when the first pixel is capable of emitting white light at a DCIP3 white point, greater than 1%, greater than 3%, greater than 5%, greater than 10%, greater than 25%, or greater than 50% of photons of light of light emitted by the first pixel is emitted from a plasmon mode of the first sub-pixel.

11. The device of claim 1, wherein greater than 1%, greater than 5%, greater than 10%, greater than 15%, greater than 20%, or greater than 25% of an absolute EQE of the first pixel is attributable to emission from a plasmon mode of the first sub-pixel.

12. The device of claim 1, wherein greater than 1%, greater than 5%, greater than 10%, greater than 15%, greater than 20%, or greater than 25% of the EQE of the OLED when rendering a uniform D65 white point image is attributable to emission from a plasmon mode.

13.-47. (canceled)

48. The device of claim 1, the first pixel further comprising a third sub-pixel.

49. The device of claim 48, the first pixel further comprising:
a fourth sub-pixel having at least one structure selected from a group consisting of:
a second cavity structure or bottom emission structure configured to emit yellow light; and
a second plasmonic stack configured to emit yellow light;
wherein:
the first sub-pixel is configured to emit blue light;
the second sub-pixel is configured to emit red light; and
the third sub-pixel comprises at least one structure selected from a group consisting of:
a third cavity structure or bottom emission structure configured to emit green light; and
a third plasmonic stack configured to emit green light.

50. The device of claim 48, the first pixel further comprising:
a fourth sub-pixel comprising at least one structure selected from a group consisting of:
a second cavity structure or bottom emission structure configured to emit blue light having a first peak wavelength; and
a second plasmonic stack configured to emit blue light having the first peak wavelength;
wherein:
the first sub-pixel is configured to emit blue light having a second peak wavelength different from the first peak wavelength;
the second sub-pixel comprises at least one structure selected from a group consisting of:
a third cavity stack or bottom emission stack configured to emit red light; and
a second plasmonic stack is configured to emit red light; and
the third sub-pixel comprises at least one structure selected from a group consisting of:
a fourth cavity stack or bottom emission stack configured to emit green light; and
a third plasmonic stack configured to emit green light.

51. The device of claim 48, the first pixel further comprising:
a fourth sub-pixel configured to emit green light and comprising a structure selected from a group consisting of: a cavity, a plasmonic device, and a bottom-emission device;
wherein:
the first sub-pixel is configured to emit blue light having a first peak wavelength;
the second sub-pixel is configured to emit blue light having a second peak wavelength different from the first peak wavelength;
the third sub-pixel is configured to emit red light from a structure selected from a group consisting of: a cavity structure, a plasmonic device, and a bottom-emission device.

52. (canceled)

53. The device of claim 48, wherein:
the first sub-pixel is configured to emit blue light;
the second sub-pixel is configured to emit red light; and
the third sub-pixel comprises a second plasmonic stack and is configured to emit green light.

54.-63. (canceled)

64. The device of claim 1, wherein at least one sub-pixel in the first pixel comprises a tandem device.

65.-73. (canceled)

74. A consumer electronic device comprising the device of claim 1.

75. The consumer electronic device of claim 74, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.

76.-80. (canceled)

81. A device comprising:
a full color organic light emitting diode (OLED) having a plurality of pixels, wherein each pixel comprises a plurality of sub-pixels, and
wherein at least one sub-pixel of the plurality of sub-pixels is configured differently from the other sub-pixels by at least one selected from a group consisting of: a different angular emission profile, and a different cathode material.
